(19) United States
(12) Patent Application Publication
(10) Pub. No.: US 2019/0326836 A1
(43) Pub. Date: Oct. 24, 2019

(54) Phase Transformation in Relaxor Ferroelectric Single Crystals for Blast Sensor

(71) Applicant: The Government of the United States of America, as represented by the Secretary of the Navy, Arlington, VA (US)

(72) Inventors: Peter Finkel, Baltimore, MD (US); Margo Staruch, Alexandria, VA (US); Timothy B. Bentley, Rockville, MD (US)

(21) Appl. No.: 16/382,752

(22) Filed: Apr. 12, 2019

Related U.S. Application Data
(60) Provisional application No. 62/660,054, filed on Apr. 19, 2018.

(51) Int. Cl. H02N 2/18; H01L 41/053; H01L 41/113; H01L 41/18

(52) U.S. Cl. CPC H02N 2/18; H01L 41/18; H01L 41/113; H01L 41/0536

(57) ABSTRACT

Domain engineered Pb(In_{1/2}Nb_{1/2})O₃—Pb(Mg_{1/3}Nb_{2/3})O₃—PbTiO₃ (PIN-PMN-PT) single crystals show an induced rhombohedral (FR)—orthorhombic (FO) phase transition under uniaxial stress or/and applied electric field. A blast sensor includes a fixture holding a single crystal of PIN-PMN-PT; a diaphragm exposed to an exterior environment; a strain transfer rod configured to transfer pressure from the diaphragm to the crystal; and an analog/digital converter (ADC) configured to receive electrical output from the crystal when the crystal is subjected to pressure.

### CROSS-REFERENCE TO RELATED APPLICATIONS

This application is related to commonly-owned US Patent Application Publication No. 2019-0058107 and to commonly-owned U.S. Pat. No. 9,490,728.

This Application claims the benefit of U.S. Provisional Application 62/660,054 filed on Apr. 19, 2018, the entirety of which is incorporated herein by reference.

### BACKGROUND

With exposure of an individual to a blast event, mild traumatic brain injury (mTBI) may occur that can cause lasting damage and that poses a greater threat if the individual is exposed to a second event shortly thereafter. The symptoms of mTBI may not manifest until after the initial injury, and can be subtle at first. In addition, mTBI may cause confusion or loss of memory that can result in inconsistent reporting of the event.

To correlate the motion of the head to any potential injury as determined from modeling or other experimental testing, it is desirable to measure the acceleration of the head as well as the profile of the blast wave, in particular the peak overpressure of the blast wave.

Most current gauge pressure sensors or differential pressure sensors cannot operate at high frequencies. Because a typical blast wave can have a rise time of ˜10 μs corresponding to a frequency of 100 kHz, piezoelectric pressure sensors appear to be the only technology currently available to measure such fast events. These sensors require a charge amplifier and power source for operation. In addition, current piezoelectric sensors deliver maximum output at resonance and are therefore narrow bandwidth.

A need exists for an improved blast sensor.

### BRIEF SUMMARY

In one embodiment, a method of recording the characteristics of a blast wave includes subjecting a Pb(In_{1/2}Nb_{1/2})O₃—Pb(Mg_{1/3}Nb_{2/3})O₃—PbTiO₃ (PIN-PMN-PT) single crystal to an initial blast wave and recording the voltage from the crystal over time, wherein the recording represents the characteristics of the blast wave.

In a further embodiment, a blast sensor includes a fixture holding a single crystal of PIN-PMN-PT; a diaphragm exposed to an exterior environment; a strain transfer rod configured to transfer pressure from the diaphragm to the crystal; and an analog/digital converter (ADC) configured to receive electrical output from the crystal when the crystal is subjected to pressure.

### BRIEF DESCRIPTION OF THE DRAWINGS

FIG. 1 is a schematic illustration of a fixture used with a PIN-PMN-PT crystal for blast sensing.

FIG. 2A shows corresponding electric potential (ϕ)—stress curves in the linear piezoelectric (open circles) and phase transition (open triangles) regimes, with peaks circled. FIG. 2B shows how Friedlander waveform Ps and t* can be extracted from a measured profile in order to reconstruct a blast event.

FIG. 3 shows exemplary data from a sensor arrangement as shown in FIG. 1.

### DETAILED DESCRIPTION

Definitions

Before describing the present invention in detail, it is to be understood that the terminology used in the specification is for the purpose of describing particular embodiments, and is not necessarily intended to be limiting. Although many methods, structures and materials similar, modified, or equivalent to those described herein can be used in the practice of the present invention without undue experimentation, the preferred methods, structures and materials are described herein. In describing and claiming the present invention, the following terminology will be used in accordance with the definitions set out below.

As used herein, the singular forms “a”, “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±10% of that stated.

Overview

Domain engineered Pb(In_{1/2}Nb_{1/2})O₃—Pb(Mg_{1/3}Nb_{2/3})O₃—PbTiO₃ (PIN-PMN-PT) single crystals show an induced rhombohedral (FR)—orthorhombic (FO) phase transition under uniaxial stress or/and applied electric field. These crystals furthermore exhibit unusual lack of fatigue after one million strain cycles as shown by Finkel et al., Phys. Status Solidi A 209, 2108 (2012). Such PIN-PMN-PT single crystals, undergoing an induced phase transformation caused by a blast wave, can be used to detect and characterize a blast wave as part of a helmet-borne sensor package.

A pressure sensor uses the large voltage produced cycling through a stress-induced phase transformation, which is a threshold phenomenon. This results in a low- or zero-power sensor where the response is frequency-independent up to the rise time of the effect, which is comparable to the rise time of a blast event.

### EXAMPLES

PIN-PMN-PT single crystals were purchased from CTG Advanced Materials and were 4×4×12 mm in size. Crystals were (011) cut and electrically poled with Cr/Au electrodes on the (011) faces. This domain engineering is necessary to be able to induce a rhombohedral to orthorhombic phase transformation with the application of uniaxial stress along the <001> direction of the crystal (long axis).

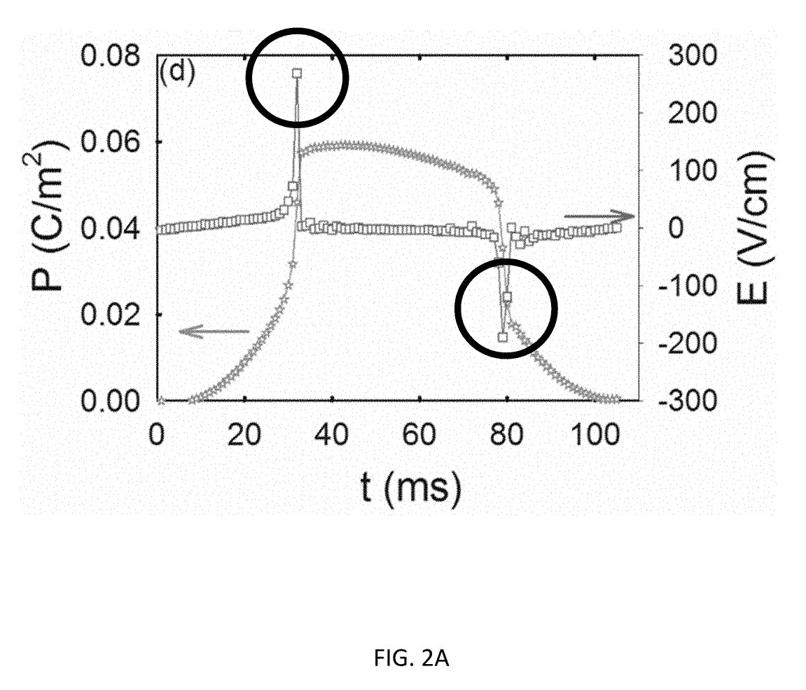

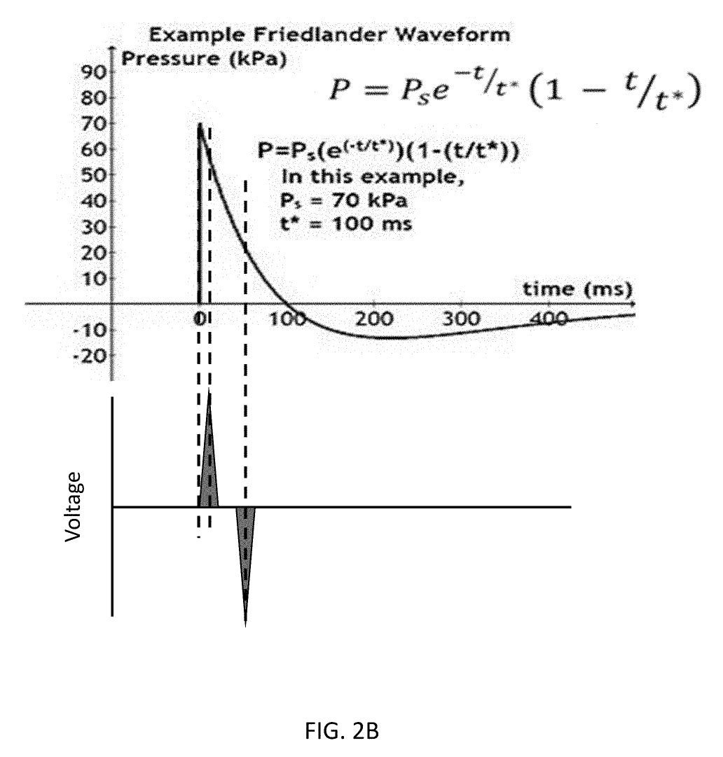

An induced phase transformation occurs at some critical stress (σ_{c}) that can be accurately determined for each crystal, as shown in the stress-strain curve in FIG. 2(a) of Moyet et al., “Non-resonant electromechanical energy harvesting using inter-ferroelectric phase transitions” Appl. Phys. Lett. 107, 172901 (2015), which is incorporated herein by reference for the purposes of disclosing techniques relating to PIN-PMN-PT crystals. As the crystal is stressed past σ_{c}, a large voltage spike of ˜800 V was produced as well as a large jump in strain. Both of these occur with a rise time of <100 μs (limited by the data logger), as shown in FIGS. 2(c) and (d) of Moyet et al.

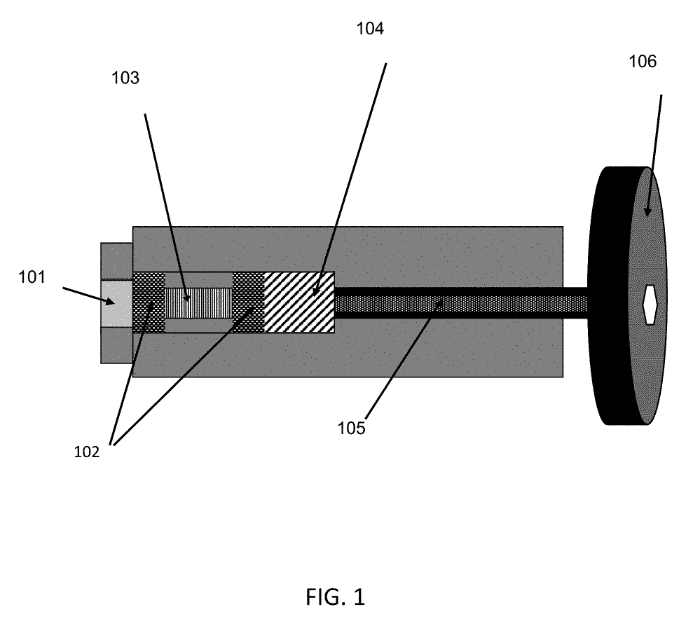

Prepared crystals were installed in a pressure sensor for purposes of testing, as schematically illustrated in FIG. 1. The primary component of the pressure sensor is an aluminum cylinder with two windows allowing for positioning of the crystal and to allow passage for wiring. The center of the cylinder has been bored out to hold the active piezoelectric crystal 103 and other necessary components as shown in the cross-sectional schematic of FIG. 1. The PIN-PMN-PT crystal 103 is positioned between two MACOR® ceramic cylinders 102 that have a layer of KAPTON® tape on the side in contact for the crystal for additional compliance and electrical insulation. This sensor can also be operated while the crystal is under uniaxial compressive stress, which can tune the value of critical stress (σ_{c}) that would be needed to trigger the phase transformation. This is accomplished through the use of a polyurethane spring 104 that will allow controllable stress when the screw 101 is tightened.

A strain transfer rod 105 is directly connected to a diaphragm 106 to convert a pressure wave (e.g., a blast wave) into a force on the piezocrystal. The base of the diaphragm is also machined out of aluminum and screws to the end of the aluminum cylinder. The base is then covered with a thin copper foil, and the strain transfer rod is fitted through the center and secured to the foil with two screws (one on either side). This design permits several different diaphragms can be added to the pressure sensor, as the area is inversely proportional to the expected or desired pressure values to measure to ensure that the same critical force is applied to the piezocrystal to induce the phase transformation.

As seen in FIGS. 2A and 2B, data measured following exposure of a PIN-PMN-PT crystal to a blast wave can be used to reconstruct the wave. FIG. 2A shows corresponding electric potential (ϕ)—stress curves in the linear piezoelectric (open circles) and phase transition (open triangles) regimes, with peaks circled. FIG. 2B shows how Friedlander waveform Ps and t* can be extracted from a measured profile in order to reconstruct a blast event.

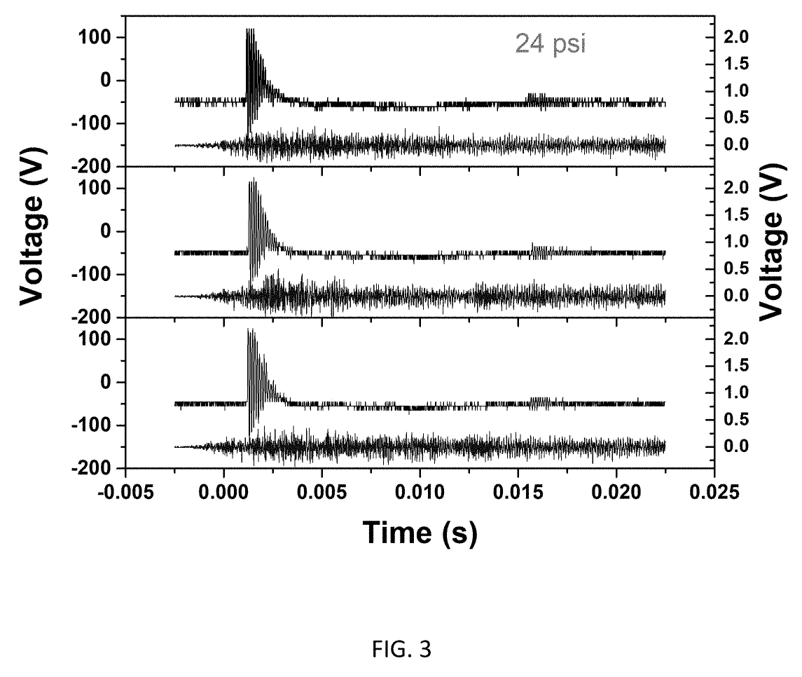

With the sensor loaded into the shock tube, shots were done at 10, 17, and 24 psi with resulting data seen in FIG. 3.

### Further Embodiments

In trials the sensor was connected to a digital sampling oscilloscope. In the field a crystal might be electrically connected to analog/digital converter (ADC) configured to receive electrical output from the crystal, and a digital recorder configured to receive the output of the ADC. In embodiments, a sensor package further comprises hardware and software configured to receive the output of the ADC and compare it to a stored data in order to determine whether mTBI might have occurred from a recorded blast. A sensor package is optionally configured for attachment to the interior or exterior of a helmet or otherwise being integrated into a helmet.

It is believed that the overall size of the device could be significantly reduced, including the active PIN-PMN-PT crystal, making the scale of this device comparable to existing technologies while still providing sufficient voltage for readoff without amplification. However, it might be desirable in some situations to incorporate an analog buffer or amplifier in the signal chain.

Moreover, the materials for the overall fixture as well as the spring and diaphragm could be modified without changing functionality.

Advantages

This mode of using the phase transformation not only produces several hundred volts during the transformation that would be more than sufficient for readoff without amplification, but is also a threshold effect and therefore does not depend on the frequency. This provides several advantages including:
(1) a broadband capability, as the voltage output is independent of the rise time of the blast event;
(2) a passive sensor with large output voltage that is induced by the pressure wave itself; and
(3) possibly eliminating the need for charge amplifiers or other signal conditioning as compared to conventional ferroelectric-based devices, thus decreasing the total energy consumption of sensor and decrease overall size and weight of the total packaging.

Concluding Remarks

All documents mentioned herein are hereby incorporated by reference for the purpose of disclosing and describing the particular materials and methodologies for which the document was cited.

Although the present invention has been described in connection with preferred embodiments thereof, it will be appreciated by those skilled in the art that additions, deletions, modifications, and substitutions not specifically described may be made without departing from the spirit and scope of the invention. Terminology used herein should not be construed as being “means-plus-function” language unless the term “means” is expressly used in association therewith.

### REFERENCES

U.S. Pat. Nos. 8,604,676, 9,490,728, and 9,048,762

Finkel et al., “Phase switching at low field and large sustainable strain output in domain engineered ferroic crystals.” Phys. Status Solidi A 209, 2108 (2012)

Moyet et al., “Non-resonant electromechanical energy harvesting using inter-ferroelectric phase transitions” Appl. Phys. Lett. 107, 172901 (2015)

What is claimed is:

1. A pressure sensor comprising:
a fixture holding a single crystal of Pb(In_{1/2}Nb_{1/2})O₃—Pb(Mg_{1/3}Nb_{2/3})O₃—PbTiO₃;
a diaphragm exposed to an exterior environment;
a strain transfer rod configured to transfer pressure from the diaphragm to the crystal; and
an analog/digital converter (ADC) configured to receive electrical output from the crystal when the crystal is subjected to pressure.

2. The pressure sensor of claim 1, further comprising a digital recorder configured to receive and store an output of the ADC.

3. The pressure sensor of claim 1, further comprising hardware and software configured to receive an output of the ADC and compare it to stored data.

4. The pressure sensor of claim 1, configured to be mounted to a helmet.

5. The pressure sensor of claim 1, further comprising an analog buffer and/or amplifier configured to increase the electrical output from the crystal prior to arrival at the ADC

6. A helmet comprising:
a protective shell defining an exterior and interior of the helmet; and
a pressure sensor comprising a fixture holding a single crystal of Pb(In_{1/2}Nb_{1/2})O₃—Pb(Mg_{1/3}Nb_{2/3})O₃—PbTiO₃; a diaphragm exposed the exterior; a strain transfer rod configured to transfer pressure from the diaphragm to the crystal; an analog/digital converter (ADC) configured to receive electrical output from the crystal when the crystal is subjected to pressure; and a digital recorder configured to receive and store the output of the ADC.

7. The helmet of claim 6, further comprising hardware and software configured to receive an output of the ADC and compare it to stored data.

8. The helmet of claim 6, further comprising an analog buffer and/or amplifier configured to increase the electrical output from the crystal prior to arrival at the ADC.

9. A method of recording a pressure wave, comprising:
providing a pressure sensor comprising a fixture holding a single crystal of Pb(In_{1/2}Nb_{1/2})O₃—Pb(Mg_{1/3}Nb_{2/3})O₃—PbTiO₃, a diaphragm, a strain transfer rod configured to transfer pressure from the diaphragm to the crystal, an analog/digital converter (ADC) configured to receive electrical output from the crystal when the crystal is subjected to pressure, and a digital recorder configured to receive and store the output of the ADC; and
subjecting the diaphragm to a pressure wave, thereby resulting in a time-varying electrical signal from the crystal which is recorded in the digital recorder and representative of the pressure wave.

10. The method of claim 7, wherein the pressure wave is a blast wave.

11. The method of claim 9, wherein an analog buffer and/or amplifier operates to increase the electrical output from the crystal prior to arrival at the ADC.
